(19) United States
(12) Patent Application Publication
(10) Pub. No.: US 2022/0352221 A1
(43) Pub. Date: Nov. 3, 2022

(54) IMAGE SENSING DEVICE AND METHOD FOR MANUFACTURING THE SAME

(71) Applicant: SK hynix Inc., Icheon-si (KR)

(72) Inventor: Sun Ho OH, Icheon-si (KR)

(21) Appl. No.: 17/545,558

(22) Filed: Dec. 8, 2021

(30) Foreign Application Priority Data
Apr. 30, 2021 (KR) 10-2021-0056619

(51) Int. Cl. H01L 27/146

(52) U.S. Cl. CPC H01L 27/14612; H01L 27/14643; H01L 27/14603; H01L 27/14689

(57) ABSTRACT

An image sensing device is provided to include a substrate layer structured to include a plurality of photoelectric conversion that respond to incident light to generate electrons, and a plurality of floating diffusion regions coupled to the plurality of photoelectric conversion regions, respectively, and structured to store the electrons generated by the plurality of photoelectric conversion regions, respectively; a first dielectric layer disposed over the substrate layer; and a second dielectric layer disposed over the first dielectric layer, and configured to include a plurality of metal lines and a pixel transistor. The pixel transistor includes a gate electrode configured to receive a control signal for the pixel transistor; a channel region formed under the gate electrode; and an insulation layer between the gate electrode and the channel region to isolate the gate electrode and the channel region from each other, and isolate adjacent metal lines from each other.

### CROSS-REFERENCE TO RELATED APPLICATION

This patent document claims the priority and benefits of Korean patent application No. 10-2021-0056619, filed on Apr. 30, 2021, the disclosure of which is incorporated by reference in its entirety as part of the disclosure of this patent document.

### TECHNICAL FIELD

The technology and implementations disclosed in this patent document generally relate to an image sensing device.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smart phones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology provide an image sensing device miniaturized in size while securing a region for pixel transistors.

In accordance with an embodiment of the disclosed technology, an image sensing device is provided to include a substrate layer structured to include a plurality of photoelectric conversion regions that respond to incident light to generate electrons, and a plurality of floating diffusion regions coupled to the plurality of photoelectric conversion regions, respectively, and structured to store the electrons generated by the plurality of photoelectric conversion regions, respectively, a first dielectric layer disposed over the substrate layer and a second dielectric layer disposed over the first dielectric layer and including a plurality of metal lines and a pixel transistor, wherein the pixel transistor includes a gate electrode configured to receive a control signal for the pixel transistor, a channel region formed under the gate electrode and an insulation layer between the gate electrode and the channel region to isolate the gate electrode and the channel region from each other, and isolate adjacent metal lines from each other.

In some implementations, the second dielectric layer includes an additional pixel transistor that is adjacent to the pixel transistor, and the insulation layer is configured to isolate the pixel transistor and the additional pixel transistors from each other.

In some implementations, the first dielectric layer includes a plurality of transfer gates configured to transmit the electrons generated by the plurality of photoelectric conversion regions to the plurality of floating diffusion region.

In some implementations, each of the plurality of the transfer gates is configured to overlap with a corresponding photoelectric conversion regions and a corresponding floating diffusion regions.

In some implementations, the pixel transistor is configured to overlap with at least one of the transfer gates.

In some implementations, the pixel transistor is implemented as a drive transistor configured to amplify a signal corresponding to electrons received from the plurality of floating diffusion regions, a selection transistor configured to selectively output the signal, a reset transistor configured to reset a voltage of the floating diffusion region, or any other transistor.

In some implementations, the plurality of photoelectric conversion regions includes four photoelectric conversion regions that are arranged in a matrix array to be adjacent to each other and one floating diffusion regions is disposed at a center of the matrix array to have portions overlapping with the four photoelectric conversion regions.

In some implementations, the pixel transistor is coupled to at least two floating diffusion regions adjacent to each other.

In some implementations, the pixel transistor is coupled to one floating diffusion region.

In some implementations, the substrate layer further includes a plurality of storage diode regions configured to store the electrons, and the first dielectric layer includes a plurality of storage gates configured to transmit the electrons generated by the plurality of photoelectric conversion regions to the plurality of storage diode regions and a plurality of transfer gates configured to transmit the electrons stored in the plurality of storage diode regions to the plurality of floating diffusion regions.

In some implementations, each of the plurality of storage gates includes a recessed portion extending in a direction from one surface of the first dielectric layer to the substrate layer and having a predetermined length.

In some implementations, each of the plurality of storage gates is disposed to overlap with a corresponding photoelectric conversion region and a corresponding storage diode region.

In some implementations, each of the plurality of transfer gates is disposed to overlap with a corresponding storage diode region and a corresponding floating diffusion region.

In some implementations, the pixel transistor is disposed to overlap with at least one of the plurality of storage gates.

In some implementations, the gate electrode includes same material as the metal lines.

In accordance with another embodiment of the disclosed technology, a method for manufacturing an image sensing device may include forming a photoelectric conversion region in a substrate layer, the photoelectric conversion region configured to produce electrons in response to a reception of incident light, forming a floating diffusion region in the substrate layer, the floating diffusion region coupled to the photoelectric conversion region and configured to store the electrons produced in the photoelectric conversion region, forming a transfer gate at an upper portion of the substrate layer, forming a first dielectric layer by depositing a first dielectric material over the transfer gate, forming a semiconductor region over the first dielectric layer, forming a pixel transistor including a source region, a channel region, and a drain region in the semiconductor region, depositing a second dielectric material over the semiconductor region to provide a second dielectric layer and forming a metal line and a gate electrode in the second dielectric layer.

In some implementations, the method for manufacturing the image sensing device may further include forming a storage diode region in the substrate layer and forming a storage gate including a recessed portion that extends to a predetermined length in a direction from an upper portion of the substrate layer to a lower portion of the substrate layer.

In some implementations, the gate electrode is formed through a same process for forming the metal line.

In some implementations, the pixel transistor is formed to overlap with the transfer gate.

In some implementations, the gate electrode is formed to overlap with the source region of the pixel transistor.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on an embodiment of the disclosed technology.

FIG. 2 is a schematic diagram illustrating an example of a unit pixel group included in an image sensing device based on an embodiment of the disclosed technology.

FIG. 3 is a cross-sectional view illustrating an example of some parts of the unit pixel group taken along a first cutting line shown in FIG. 2.

FIG. 4 is a circuit diagram illustrating an example of an equivalent circuit of the unit pixel group based on an embodiment of the disclosed technology.

FIGS. 5 to 10 are cross-sectional views illustrating examples of methods for forming a pixel transistor based on an implementation of the disclosed technology.

FIG. 11 is a schematic diagram illustrating an example of a unit pixel group included in an image sensing device based on another embodiment of the disclosed technology.

FIG. 12 is a cross-sectional view illustrating an example of a unit pixel group taken along a second cutting line shown in FIG. 11.

FIG. 13 is a circuit diagram illustrating an example of an equivalent circuit of a unit pixel group based on another embodiment of the disclosed technology.

FIG. 14 is a schematic diagram illustrating an example of a unit pixel group included in an image sensing device based on still another embodiment of the disclosed technology.

FIG. 15 is a cross-sectional view illustrating an example of a unit pixel group taken along a third cutting line shown in FIG. 14.

FIG. 16 is a circuit diagram illustrating an example of an equivalent circuit of a unit pixel group based on still another embodiment of the disclosed technology.

### DETAILED DESCRIPTION

This patent document provides implementations and examples of an image sensing device miniaturized in size while securing a region in which pixel transistors are arranged. Some implementations of the disclosed technology relate to the image sensing device configured in a manner that pixel transistors to be included in the image sensing device are formed in a different layer from a layer in which transfer gates are disposed. Thus, it is possible to secure or guarantee a region for the pixel transistors, resulting in an increased degree of freedom in forming such pixel transistors. The disclosed technology provides the image sensing device which can form gate electrodes of the pixel transistors together with metal lines, resulting in a simplified process for forming such pixel transistors. The disclosed technology provides the image sensing device which can allow the metal lines adjacent to each other to be isolated from each other by an insulation layer formed to separate gate electrodes of the pixel transistors from channel regions of the pixel transistors. The disclosed technology provides the image sensing device which can form a storage transistor and a storage diode region in the region that has been guaranteed by forming the pixel transistors in a different layer from the transfer gates, thereby performing a global shutter operation.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

As the image sensing device is miniaturized in size, a region of unit pixels to be included in the image sensing device can be reduced in size.

If the region of each unit pixel is miniaturized, a layout area in which photoelectric conversion regions and pixel transistors that are to be used for the image sensing device are arranged can be reduced in size. As the region in which pixel transistors are arranged is reduced, a size of a gate of each pixel transistor needs to be reduced as well.

If the gate size of each of the pixel transistors is reduced, noise may occur in operation of the pixel transistors, or short channel effects may occur in operation of the pixel transistors.

Due to occurrence of such noise and short channel effects in the pixel transistors, unexpected noise may occur in signals detected by the image sensing device. Various implementations of the disclosed technology provide an image sensing device that can address the issues as discussed above. For example, the image sensing device of the disclosed technology can secure a region for pixel transistors with an increased degree of freedom in disposing pixel transistors.

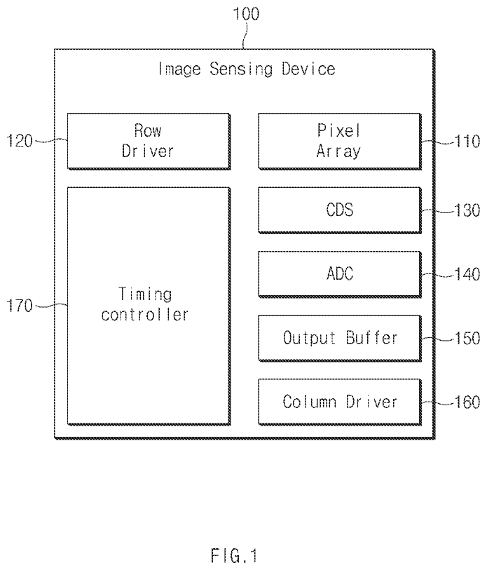

FIG. 1 is a block diagram illustrating an image sensing device according to an embodiment of the disclosed technology.

Referring to FIG. 1, the image sensing device 100 may include a pixel array 110, a row driver 120, a correlated double sampler (CDS) 130, an analog-digital converter (ADC) 140, an output buffer 150, a column driver 160 and a timing controller 170. The components of the image sensing device 100 illustrated in FIG. 1 are discussed by way of example only, and this patent document encompasses numerous other changes, substitutions, variations, alterations, and modifications.

The pixel array 110 may include a plurality of unit imaging pixels arranged in rows and columns. In one example, the plurality of unit imaging pixels can be arranged in a two dimensional pixel array including rows and columns. In another example, the plurality of unit imaging pixels can be arranged in a three dimensional pixel array. The plurality of unit pixels may convert an optical signal into an electrical signal on a unit pixel basis or a pixel group basis, where unit pixels in a pixel group share at least certain internal circuitry. The pixel array 110 may receive driving signals, including a row selection signal, a pixel reset signal and a transfer signal, from the row driver 120. Upon receiving the driving signal, corresponding imaging pixels in the pixel array 110 may be activated to perform the operations corresponding to the row selection signal, the pixel reset signal, and the transfer signal.

The row driver 120 may activate the pixel array 110 to perform certain operations on the imaging pixels in the corresponding row based on commands and control signals provided by controller circuitry such as the timing controller 170. In some implementations, the row driver 120 may select one or more imaging pixels arranged in one or more rows of the pixel array 110. The row driver 120 may generate a row selection signal to select one or more rows among the plurality of rows. The row driver 120 may sequentially enable the pixel reset signal for resetting imaging pixels corresponding to at least one selected row, and the transfer signal for the pixels corresponding to the at least one selected row. Thus, a reference signal and an image signal, which are analog signals generated by each of the imaging pixels of the selected row, may be sequentially transferred to the CDS 130. The reference signal may be an electrical signal that is provided to the CDS 130 when a sensing node of an imaging pixel (e.g., a floating diffusion region node) is reset, and the image signal may be an electrical signal that is provided to the CDS 130 when photocharges generated by the imaging pixel are accumulated in the sensing node.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

In some implementations, the CDS 130 may transfer the reference signal and the image signal of each of the columns as a correlate double sampling signal to the ADC 140 based on control signals from the timing controller 170.

The ADC 140 is used to convert analog CDS signals into digital signals. In some implementations, the ADC 140 may be implemented as a ramp-compare type ADC. The ramp-compare type ADC may include a comparator circuit for comparing the analog pixel signal with a reference signal such as a ramp signal that ramps up or down, and a timer for counting until a voltage of the ramp signal matches the analog pixel signal. In some embodiments of the disclosed technology, the ADC 140 may convert the correlate double sampling signal generated by the CDS 130 for each of the columns into a digital signal, and output the digital signal. The ADC 140 may perform a counting operation and a computing operation based on the correlate double sampling signal for each of the columns and a ramp signal provided from the timing controller 170. In this way, the ADC 140 may eliminate or reduce noises such as reset noise arising from the imaging pixels when generating digital image data.

The ADC 140 may include a plurality of column counters. Each column of the pixel array 110 is coupled to a column counter, and image data can be generated by converting the correlate double sampling signals received from each column into digital signals using the column counter. In another embodiment of the disclosed technology, the ADC 140 may include a global counter to convert the correlate double sampling signals corresponding to the columns into digital signals using a global code provided from the global counter.

The output buffer 150 may temporarily hold the column-based image data provided from the ADC 140 to output the image data. In one example, the image data provided to the output buffer 150 from the ADC 140 may be temporarily stored in the output buffer 150 based on control signals of the timing controller 170. The output buffer 150 may provide an interface to compensate for data rate differences or transfer rate differences between the image sensing device 100 and other devices.

The column driver 160 may select a column of the output buffer upon receiving a control signal from the timing controller 170, and sequentially output the image data, which are temporarily stored in the selected column of the output buffer 150. In some implementations, upon receiving an address signal from the timing controller 170, the column driver 160 may generate a column selection signal based on the address signal and select a column of the output buffer 150, outputting the image data as an output signal from the selected column of the output buffer 150.

The timing controller 170 may control operations of the row driver 120, the ADC 140, the output buffer 150 and the column driver 160.

The timing controller 170 may provide the row driver 120, the column driver 160 and the output buffer 150 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

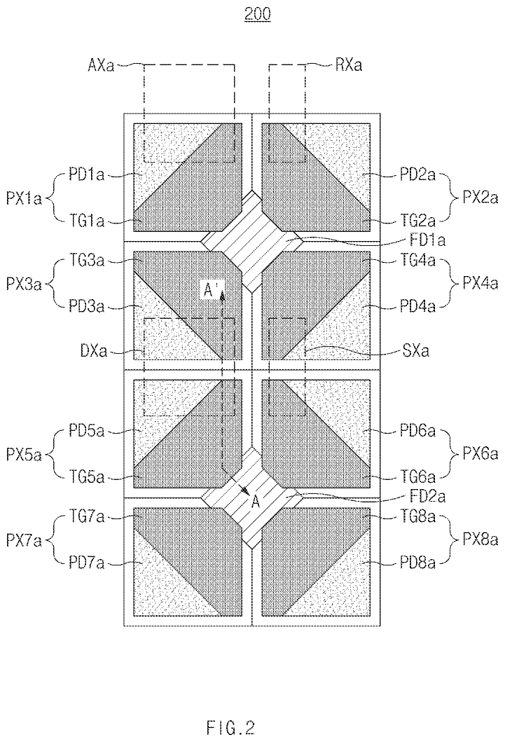

FIG. 2 is a schematic diagram illustrating an example of a unit pixel group 200 included in an image sensing device (e.g., 100 of FIG. 1) based on an embodiment of the disclosed technology. For example, the pixel array (e.g., 110 of FIG. 1) may include a plurality of unit pixel groups 200 repeatedly arranged therein.

Each unit pixel group 200 may include a plurality of unit pixels PX1a˜PX8a. Each unit pixel (e.g., PX1a) may include a photoelectric conversion region (e.g., PD1a) and a transfer gate TG1a.

FIG. 2 illustrates an example of the unit pixel group 200 including eight unit pixels PX1a˜PX8a. The unit pixel group 200 may include a plurality of unit pixels PX1a˜PX8a, floating diffusion regions FD1a and FD2a configured to store electrons generated by the photoelectric conversion regions PD1a˜PD8a, and one or more pixel transistors DXa, SXa, RXa, and AXa that are formed in a different layer from the transfer gates TG1a˜TG8a.

A photoelectric conversion region (e.g., PD1a) and a transfer gate (e.g., TG1a) included in each unit pixel (e.g., PX1a) may be respectively referred to as a photoelectric conversion region PD1a and a transfer gate TG1a that correspond to each other.

The transfer gate (e.g., TG1a) included in the unit pixel (e.g., PX1a) may be formed to overlap with the photoelectric conversion region (e.g., PD1a).

Some portions of the photoelectric conversion region PD1a may be hidden or covered by the transfer gate TG1a. The photoelectric conversion region PD1a covered by the transfer gate TG1a may be formed to extend in the direction of a floating diffusion region FD1a adjacent to the photoelectric conversion region PD1a with respect to a lower region of the transfer gate TG1a.

Although FIG. 2 shows an example of a connection structure between the photoelectric conversion region PD1a and the transfer gate TG1a included in one unit pixel PX1a, other implementations are also possible, and it should be noted that the same concept as described above can also be applied to all the photoelectric conversion regions PD1a˜PD8a included in the unit pixel group 200.

Each of the photoelectric conversion regions PD1a˜PD8a may include an organic or inorganic photodiode. For example, the photoelectric conversion regions PD1a˜PD8a may be formed in a semiconductor substrate layer, and each of the photoelectric conversion regions PD1a˜PD8a may include a stacked structure in which impurity regions (e.g., P-type impurity region and N-type impurity region) having complementary conductivities are vertically stacked.

Transfer gates TG1a˜TG8a may be formed to overlap with a floating diffusion region FD1a or a floating diffusion region FD2a. In more detail, the transfer gates TG1a˜TG4a may overlap with the floating diffusion region FD1a adjacent to the transfer gates TG1a˜TG4a, and the transfer gates TG5a˜TG8a may overlap with the floating diffusion region FD2a adjacent to the transfer gates TG5a˜TG8a. The transfer gates TG1a˜TG8a may transmit electrons generated by the photoelectric conversion regions PD1a˜PD8a to the floating diffusion regions FD1a and FD2a based on control signals applied to the transfer gates TG1a˜TG8a. In more detail, the transfer gates TG1a˜TG4a may transmit electrons generated by the photoelectric conversion regions PD1a˜PD4a to the floating diffusion region FD1a based on control signals applied to the transfer gates TG1a˜TG4a, and the transfer gates TG5a˜TG8a may transmit electrons generated by the photoelectric conversion regions PD5a˜PD8a to the floating diffusion region FD2a based on control signals applied to the transfer gates TG5a˜TG8a. In this case, the control signals applied to the transfer gates TG1a˜TG8a may be referred to as transfer control signals.

In some implementations, four adjacent unit pixels (e.g., PD1a˜PD4a) among eight unit pixels PD1a˜PD8a included in the unit pixel group 200 may be arranged to surround one floating diffusion region (e.g., FD1a). Thus, one floating diffusion region FD1a may be shared by four unit pixels included in the unit pixel group 200. In some other implementations, it is possible that one floating diffusion region FD1a may be shared by N unit pixels, N being a positive number that is not four.

In some implementation, the floating diffusion regions FD1a and FD2a included in one unit pixel group 200 may be coupled to each other through metal lines (not shown), resulting in the formation of only one sensing node.

Pixel transistors DXa, SXa, RXa, and AXa included in the unit pixel group 200 may be disposed in a different layer from the transfer gates TG1a˜TG8a. For example, the pixel transistors DXa, SXa, RXa, and AXa may be formed in a dielectric layer that is different from a dielectric layer in which the transfer gates TG1a˜TG8a are formed. In some implementations, the pixel transistors DXa, SXa, RXa, and AXa and the transfer gates TG1a˜TG8a disposed in different dielectric layers may overlap with each other.

Each of the pixel transistors DXa, SXa, RXa, and AXa may include a gate electrode configured to receive a control signal for a corresponding pixel transistor, a channel region formed under the gate electrode, and an insulation layer configured to isolate the gate electrode and the channel region from each other. In addition, each of the pixel transistors DXa, SXa, RXa, and AXa may include a source region configured to provide electrons in response to a control signal, and a drain region configured to receive electrons in response to a control signal. For example, the pixel transistor may be any one of a drive transistor DXa, a selection transistor SXa, a reset transistor RXa, and an additional transistor AXa.

A sensing node may be coupled to a gate electrode of the drive transistor DXa serving as any one of the pixel transistors. The sensing node may include the floating diffusion regions FD1a and FD2a interconnected by metal lines. The drive transistor DXa may amplify a voltage change of the sensing node connected thereto, and may thus generate a signal corresponding to the amplified voltage change.

A source region of the selection transistor SXa may be coupled to a drain region of the drive transistor DXa. In response to a control signal applied to a gate electrode of the selection transistor SXa, the selection transistor SXa may selectively output a signal corresponding to a voltage change amplified by the drive transistor DXa. In this case, the control signal applied to the gate electrode of the selection transistor SXa may be referred to as a selection control signal.

The sensing node may be coupled to a source region of the reset transistor RXa. The reset transistor RXa may reset potentials of constituent elements (e.g., floating diffusion regions FD1a and FD2a, photoelectric conversion regions PD1a˜PD8a, and the like) included in the unit pixel group 200 to a predetermined level (e.g., a pixel voltage level VDD) based on a control signal applied to a gate electrode thereof. In this case, the control signal applied to the gate electrode of the reset transistor RXa may be referred to as a reset control signal.

When the reset control signal capable of activating the reset transistor RXa is applied to the reset transistor RXa, a transfer control signal capable of activating the transfer gates TG1a˜TG8a may be applied to the transfer gates TG1a˜TG8a.

The additional transistor AXa may be a transistor other than the drive transistor DXa, the selection transistor SXa, or the reset transistor RXa. The type of the additional transistor AXa may be determined according to functions of the image sensing device (e.g., 100 of FIG. 1).

For example, the additional transistor AXa of the image sensing device 100 having a variable conversion gain may be a dual conversion gain (DCG) transistor that is capable of adjusting the conversion gain by adjusting capacitance of the sensing node.

In another embodiment, the additional transistor AXa may be an anti-blooming transistor capable of removing excess electrons. The anti-blooming transistor may remove electrons excessively generated in a photoelectric conversion region (e.g., PD1a), thereby preventing an occurrence of noise in pixel signals.

In still another embodiment, the additional transistor AXa may be a capacitive transistor connected to the sensing node. The capacitive transistor may refer to a transistor that is capable of increasing capacitance of the sensing node by connecting to the sensing node.

The positions of portions of the pixel transistors DXa, SXa, RXa, and AXa overlapping with the transfer gates TG1a˜TG8a and the shapes of the pixel transistors DXa, SXa, RXa, and AXa, which are discussed above, are merely examples. Thus, the arrangement and/or shapes of the pixel transistors DXa, SXa, RXa, and AXa can vary depending on the layout of the unit pixel group 200 and the types of the pixel transistors DXa, SXa, RXa, and AXa.

For example, as the region of the gate electrode of the drive transistor DXa increases in size, noise generated in the drive transistor DXa may decrease. Therefore, the drive transistor DXa can be formed to occupy a region as large as possible in the layout structure of the unit pixel group 200.

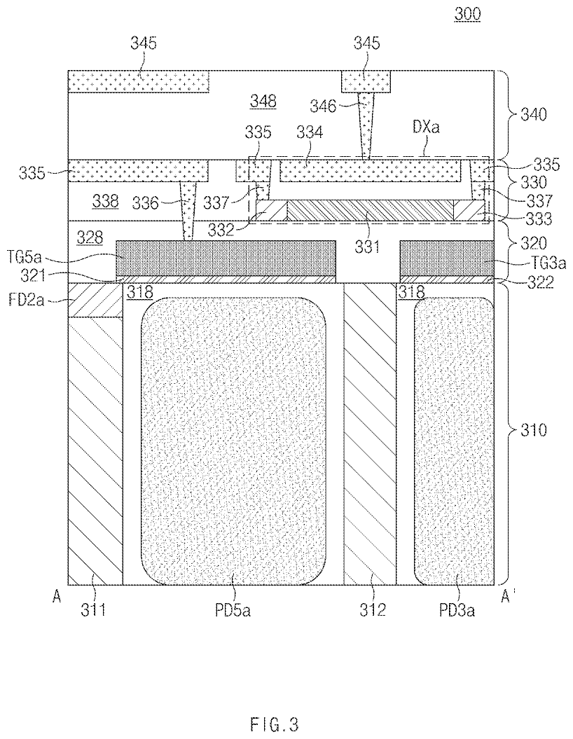

FIG. 3 is a cross-sectional view 300 illustrating an example of some parts of the unit pixel group 200 taken along a first cutting line A-A′ shown in FIG. 2.

Referring to FIG. 3, a substrate layer 310 included in the unit pixel group 200, a first dielectric layer 320 disposed over the substrate layer 310, a second dielectric layer 330 disposed over the first dielectric layer 320, and a third dielectric layer 340 disposed over the second dielectric layer 330 are shown. The first to third dielectric layers 320, 330 and 340 include dielectric material to insulate components disposed in each of the first to third dielectric layers 320, 330 and 340 from one another.

The substrate layer 310 may include isolation regions 311 and 312, a semiconductor region 318, photoelectric conversion regions PD5a and PD3a, and a floating diffusion region FD2a. Although FIG. 3 illustrates some parts of the unit pixel group 200, it should be noted that the same concept as described above can also be applied to other regions included in the unit pixel group 200.

The isolation regions 311 and 312 may be regions that physically and optically isolate the photoelectric conversion regions PD5a and PD3a adjacent to each other. For example, each of the isolation regions 311 and 312 may be doped with P-type or N-type impurities.

The semiconductor region 318 may refer to, for example, a silicon wafer or an epitaxial layer. The semiconductor region 318 may be a region including silicon doped with P-type or N-type impurities.

Each of the photoelectric conversion regions PD5a and PD3a may have a stacked structure in which impurity regions (e.g., P-type impurity region and N-type impurity region) having complementary conductivities are vertically stacked. Each photoelectric conversion region (e.g., PD5a) may generate electrons corresponding to incident light received in the corresponding pixel.

Electrons generated by the photoelectric conversion region (e.g., PD5a) may be transferred to the floating diffusion region FD2a overlapping with the transfer gate TG5a through a transfer gate (e.g., TG5a) overlapping with the photoelectric conversion region PD5a.

The floating diffusion region FD2a may store electrons generated by the photoelectric conversion region PD5a. The electrons stored in the floating diffusion region FD2a may be output as a pixel signal after passing through the sensing node SN, the drive transistor DXa, and the selection transistor (e.g., SXa of FIG. 3). In some implementations, the floating diffusion region FD2a may include a region doped with N-type impurities (hereinafter referred to as an N-type impurity doped region).

The first dielectric layer 320 formed over the substrate layer 310 may include transfer gates TG5a and TG3a, gate insulation layers 321 and 322 formed below the transfer gates TG5a and TG3a, and a passivation layer 328 formed to surround the transfer gates TG5a and TG3a.

The transfer gate (e.g., TG5a) may be formed to overlap with the photoelectric conversion region PD5a corresponding to the transfer gate TG5a.

The gate insulation layers 321 and 322 may be formed between the substrate layer 310 and the transfer gates TG5a and TG3a. In more detail, the gate insulation layer 321 may be formed between the substrate layer 310 and the transfer gate TG5a, and the gate insulation layer 322 may be formed between the substrate layer 310 and the transfer gate TG3a. Each of the gate insulation layers 321 and 322 may include an insulation material such as silicon oxide. The gate insulation layers 321 and 322 may electrically or physically isolate the substrate layer 310 from the transfer gates TG5a and TG3a. In more detail, the gate insulation layer 321 may electrically or physically isolate the transfer gate TG5a and the substrate layer 310 from each other, and the gate insulation layer 322 may electrically or physically isolate the transfer gate TG3a and the substrate layer 310 from each other.

The passivation layer 328 may isolate the adjacent transfer gates TG5a and TG3a from each other. In some implementations, the passivation layer 328 may include silicon oxide, silicon nitride, and the like.

The second dielectric layer 330 may be formed over the first dielectric layer 320. The second dielectric layer 330 may include a pixel transistor (e.g., DXa of FIG. 2) and a plurality of metal lines 335, 336, and 337.

For example, the pixel transistor formed in the second dielectric layer 330 may be implemented as the drive transistor DXa. The drive transistor DXa may include a channel region 331 formed of a semiconductor material, a source region 332 formed adjacent to the channel region 331, a drain region 333, and a gate electrode 334 formed to overlap with the channel region 331. The source region 332 and the drain region 333 may be formed by doping a P-type or N-type impurity over the semiconductor material forming the channel region 331. The semiconductor material forming the channel region 331 may include, for example, polysilicon.

The drive transistor DXa may include the gate electrode 334. The gate electrode 334 may be formed through the same process as the metal line 335 formed in the second dielectric layer 330.

The second dielectric layer 330 may include metal lines 335, 336, and 337, which interconnect a plurality of pixel transistors (e.g., SXa, RXa, and AXa of FIG. 2) or form a control signal line. In this case, the control signal line may refer to a line to which control signals for the respective pixel transistors (e.g., DXa, SXa, RXa, and AXa) are applied.

The metal lines 335, 336, and 337 may include a vertical metal line 336 connected to the transfer gate TG5a, and a vertical metal line 337 connected to the source region 332 and the drain region 333 of the drive transistor DXa. In this case, the vertical metal line 337 connected to the transfer gate TG5a may be formed across the second dielectric layer 330 and the first dielectric layer 320. The shapes of the metal lines 335, 336, and 337 may vary depending on the layout of the unit pixel group (e.g., 200 of FIG. 2). In some implementations, the gate electrode 334 and the metal line 335 may be formed through the same etching process and a metal patterning process.

The gate electrode 334 and the channel region 331 may be isolated from each other by an insulation layer 338. In some implementations, the insulation layer 338 may include silicon oxide or silicon nitride. In addition, the insulation layer 338 may isolate the gate electrode 334 and the channel region 331 from each other, may isolate different pixel transistors from each other, or may isolate the metal lines 335, 336, and 337 from each other.

A third dielectric layer 340 formed over the second dielectric layer 330 may include additional metal lines 345 and 346, and may include an isolation layer 348 formed to electrically isolate the metal lines 345 and 346 from each other. The isolation layer 348 may include silicon oxide or silicon nitride.

The additional metal lines 345 and 346 formed in the third dielectric layer 340 may couple pixel transistors (e.g., DXa) to a control signal line corresponding to the pixel transistors (e.g., DXa) or may interconnect the pixel transistors (e.g., DXa and SXa) in the same manner as the metal lines 335, 336, and 337 formed in the second dielectric layer 330.

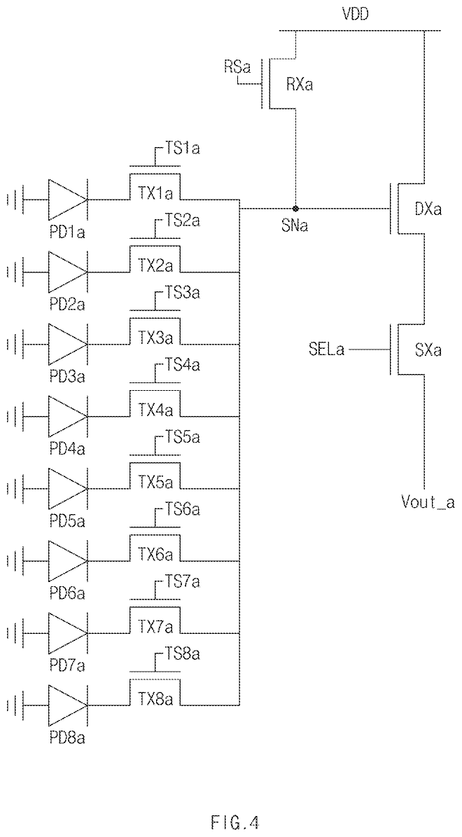

FIG. 4 is a circuit diagram illustrating an example of an equivalent circuit of the unit pixel group (e.g., 200 of FIG. 2) based on an embodiment of the disclosed technology.

FIG. 4 illustrates eight transfer transistors TX1a˜TX8a and eight photoelectric conversion regions PD1a˜PD8a respectively corresponding to the transfer transistors TX1a˜TX8a. Each transfer transistor (e.g., TX1a) may include a transfer gate (e.g., TG1a of FIG. 2) corresponding thereto.

Transfer control signals TS1a˜TS8a may be applied to the transfer transistors TX1a˜TX8a, respectively. In response to voltage levels of the transfer control signals TS1a˜TS8a, electrons generated by the photoelectric conversion regions PD1a˜PD8a may be transmitted to a sensing node SNa through the corresponding transfer transistors TX1a˜TX8a.

Eight photoelectric conversion regions PD1a˜PD8a may be coupled to one sensing node SNa through the transfer transistors TX1a˜TX8a. Thus, the sensing node SNa may be shared by the eight photoelectric conversion regions PD1a˜PD8a. The sensing node SNa may be a region configured to store electrons generated by the photoelectric conversion regions PD1a˜PD8a. In some implementations, the sensing node SNa may include one or more floating diffusion regions (e.g., FD1a and FD2a of FIG. 2).

The reset transistor RXa may remove electrons stored in the sensing node SNa and electrons of the photoelectric conversion regions PD1a˜PD8a connected to the sensing node SNa, and may thus reset the unit pixel group 200 to the pixel voltage VDD. It can be determined whether to perform a reset operation for the unit pixel group 200 based on a voltage level of a reset control signal RSa applied to the reset transistor RXa.

The drive transistor DXa may operate as a source follower transistor configured to amplify a voltage change corresponding to electrons stored in the sensing node SNa. One end of the drive transistor DXa may be coupled to the pixel voltage VDD, and the other end of the drive transistor DXa may be coupled to the selection transistor SXa.

The selection transistor SXa may determine whether to output a pixel signal Vout_a corresponding to the voltage change amplified by the drive transistor DXa. It can be determined whether to output the pixel signal Vout_a of the selection transistor SXa based on a voltage level of a selection control signal SELa applied to a gate electrode of the selection transistor SXa.

The output pixel signal Vout_a may be processed by constituent elements (e.g., CDS 130 and the like) included in the image sensing device (e.g., 100 of FIG. 1) to generate an image signal corresponding to incident light.

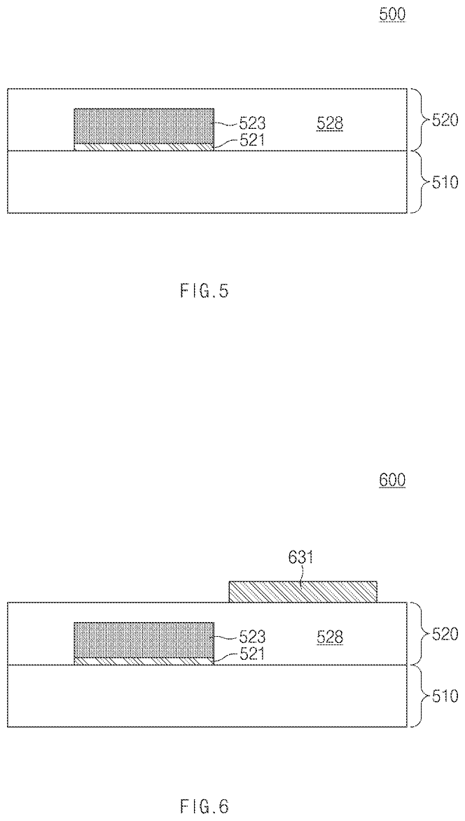

FIGS. 5 to 10 are cross-sectional views illustrating examples of methods for forming a pixel transistor based on an implementation of the disclosed technology. FIGS. 5 to 10 are shown only for illustrative purposes, and may be shown differently from the actual scale as necessary.

A cross-sectional view 500 including a first dielectric layer 520 formed over a substrate layer 510 is shown in FIG. 5. For example, the substrate layer 510 may be or include a semiconductor substrate. Although not shown in the drawings, the substrate layer 510 may include a photoelectric conversion region and a floating diffusion region that are formed by doping impurities over the semiconductor substrate.

A gate insulation layer 521 including silicon oxide or silicon nitride may be formed over the substrate layer 510 including the photoelectric conversion region and the floating diffusion region. Subsequently, a semiconductor material may be formed to overlap with the gate insulation layer 521, resulting in the formation of a transfer gate 523. The semiconductor material may include, for example, polysilicon, and may be formed through a polysilicon deposition process.

A passivation layer 528 may be formed to surround the transfer gate 523 and the gate insulation layer 521, thereby resulting in formation of the first dielectric layer 520. In this case, the transfer gates adjacent to each other may be isolated from each other by the passivation layer 528.

A cross-sectional view 600 including a semiconductor region 631 formed over the first dielectric layer 520 is shown in FIG. 6. The semiconductor region 631 may include polysilicon, and may be formed through a silicon deposition process. In this case, the deposition process may refer to a process for depositing a metal or semiconductor material formed in a thin film shape over the semiconductor substrate.

The position of each pixel transistor may be determined depending on where the semiconductor region 631 is formed. For example, when the semiconductor region 631 is formed to overlap with the transfer gate 523, the pixel transistor may overlap with the transfer gate 523. The pixel transistor is formed in a different layer from the transfer gate 523 while overlapping with the transfer gate 523, such that a formation region of the pixel transistor can be guaranteed regardless of the shape of the transfer gate 523.

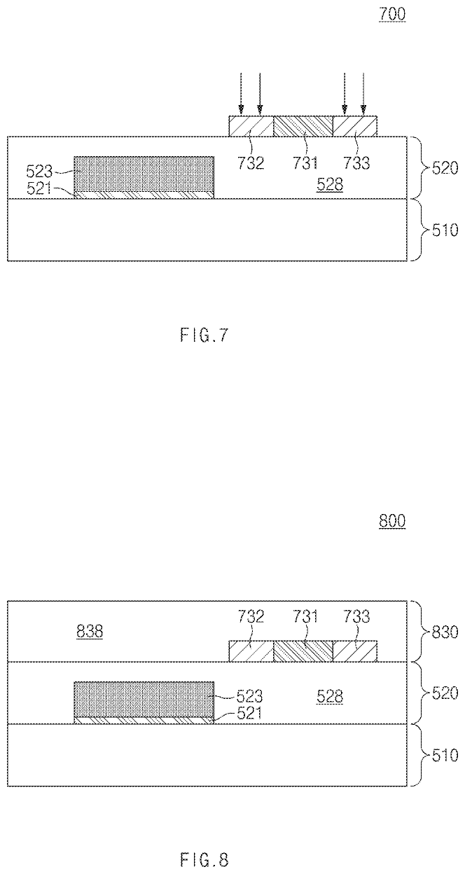

FIG. 7 illustrates a cross-sectional view 700 in which a channel region 731, a source region 732, and a drain region 733 of the pixel transistor are formed by implanting ions into a stacked semiconductor region. As can be seen from FIG. 7, the source region 732 and the drain region 733 may be formed by implanting P-type or N-type impurity ions into the semiconductor region 631 including polysilicon. As the source region 732 and the drain region 733 are formed, the channel region 731 may be defined as a region between the source region 732 and the drain region 733.

FIG. 8 illustrates a cross-sectional view 800 in which an insulation layer 838 is formed to surround the channel region 731, the source region 732, and the drain region 733. The insulation layer 838 may include silicon oxide or silicon nitride, and may be formed through the above-mentioned deposition process. The channel region 731, the source region 732, the drain region 733, and the insulation layer 838 may be included in a second dielectric layer 830.

FIG. 9 illustrates a cross-sectional view 900 in which a gate electrode 934 and a plurality of metal lines 935, 936, and 937 are formed in the second dielectric layer 830. The metal lines 935, 936, and 937 may include vertical metal lines 936 and 937 formed in a vertical direction. Further, the metal line 935 may include interconnections (or wires) through which control signal lines are coupled to the pixel transistors.

After formation of the vertical metal lines 936 and 937, the remaining metal lines 935 other than the vertical metal lines 936 and 937 may be formed. The metal lines 935, 936, and 937 may be formed through an etching process and a patterning process. A portion of the vertical metal line 936 may be formed across the first dielectric layer 520 and the second dielectric layer 830. The vertical metal line 936 formed across the first dielectric layer 520 and the second dielectric layer 830 may connect the metal line 935 to a control signal line coupled to the transfer gate 523 disposed in the first dielectric layer 520.

The gate electrode 934 may be formed together with the metal line 935 through the etching process and the patterning process. The gate electrode 934 may be formed of the same metal as the metal lines 935 and 936, and may be formed by the same process as the metal line 935, resulting in a simplified fabrication process.

In some implementations, the gate electrode 934 may be formed to overlap with the channel region 731. A thickness of the insulation layer 838 disposed between the gate electrode 934 and the channel region 731 may vary depending on the types of pixel transistors. In some implementations, the insulation layer 838 has a thickness that ranges between, for example, about 150˜300 Å.

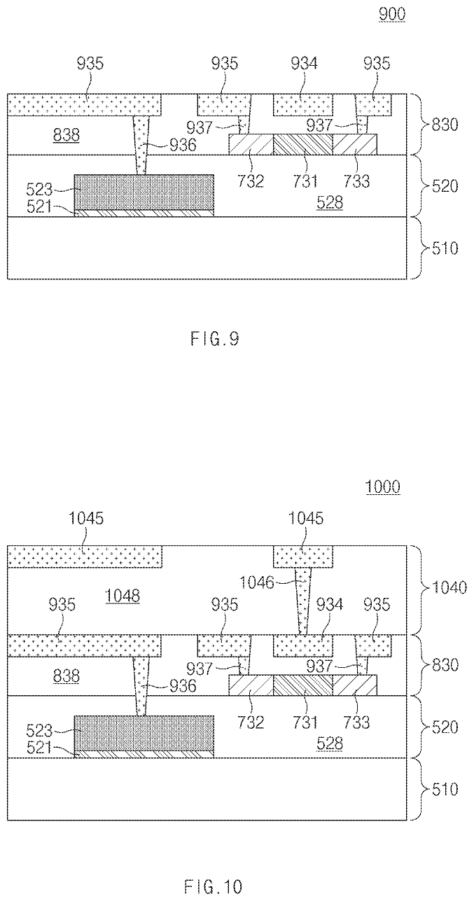

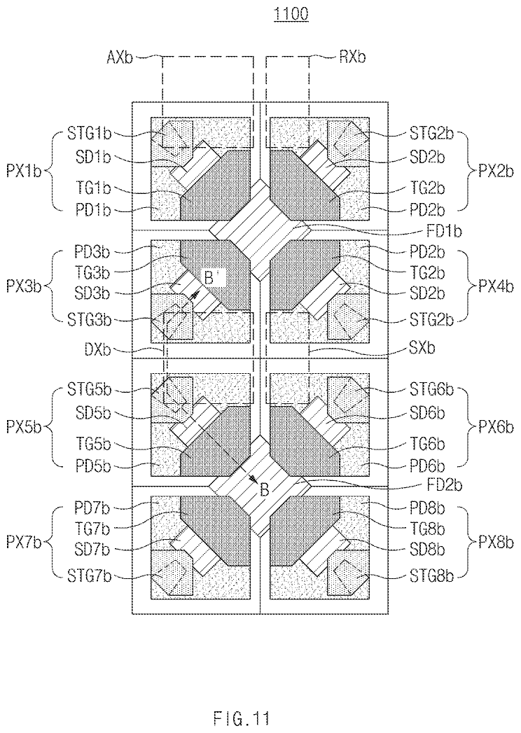

FIG. 10 illustrates a cross-sectional view 1000 in which a third dielectric layer 1040 is formed over the second dielectric layer 830. The third dielectric layer 1040 may include metal lines 1045 and 1046, and an isolation layer 1048 for isolating the metal lines 1045 and 1046 from each other. After the isolation layer 1048 is formed over the second dielectric layer 830, the metal lines 1045 and 1046 are formed in the isolation layer 1048, resulting in formation of the third dielectric layer 1040. The isolation layer 1048 may be formed through a deposition process, and the metal lines 1045 and 1046 may be formed through etching and patterning processes.

The cross-section 1000 shown in FIG. 10 may correspond to a portion of the cross-section 300 (see FIG. 3) of the unit pixel group 200 taken along the first cutting line A-A′ shown in FIG. 2.

For example, a substrate layer 510 shown in FIG. 10 may correspond to the substrate layer 310 shown in FIG. 3, and a first dielectric layer 520 shown in FIG. 10 may correspond to the first dielectric layer 320 shown in FIG. 3. In addition, the second dielectric layer 830 shown in FIG. 10 may correspond to the second dielectric layer 330 shown in FIG. 3, and the third dielectric layer 1040 shown in FIG. 10 may be matched to the third dielectric layer 340 shown in FIG. 3.

The gate electrode 334 included in the pixel transistor DXa shown in FIG. 3 may be matched to a gate electrode 934 shown in FIG. 10. In addition, the channel region 331, the source region 332, the drain region 333, and the insulation layer 338 included in the pixel transistor DXa shown in FIG. 3 may be matched to the channel region 731, the source region 732, the drain region 733, and the insulation layer 838 shown in FIG. 10, respectively.

FIG. 11 is a schematic diagram illustrating an example of a layout structure of a unit pixel group 1100 included in an image sensing device (e.g., 100 of FIG. 1) based on another embodiment of the disclosed technology. As depicted in FIG. 2, the plurality of unit pixel groups 1100 may be repeatedly arranged in a pixel array (e.g., 110 of FIG. 1).

Similar to the unit pixel group 200 shown in FIG. 2, the unit pixel group 1100 may include a plurality of unit pixels PX1b˜PX8b, a plurality of floating diffusion regions FD1b and FD2b, and a plurality of pixel transistors DXb, SXb, RXb, and AXb. For convenience of description, the unit pixel group 1100 shown in FIG. 11 will hereinafter be described centering upon characteristics different from those of the unit pixel group 200 shown in FIG. 2.

Each unit pixel (e.g., PX1b) may include a photoelectric conversion region (e.g., PD1b) configured to generate electrons corresponding to incident light, a storage gate (e.g., STG1b) configured to overlap with the photoelectric conversion region PD1b, a storage diode region (e.g., SD1b) configured to store electrons generated by the photoelectric conversion region PD1b, and a transfer gate TG1b configured to transmit electrons stored in the storage diode region SD1b to a floating diffusion region (e.g., FD1b). Although the above-mentioned description has been disclosed using only one unit pixel PX1b as an example, other implementations are also possible, and it should be noted that the same concept as described above can also be applied to all the unit pixels PX1b˜PX8b included in the unit pixel group 1100 shown in FIG. 11.

The storage gate STG1b may transmit electrons generated by the photoelectric conversion region PD1b to the storage diode region SD1b formed to overlap with the storage gate STG1b. The storage diode region (e.g., SD1b) included in the unit pixel (e.g., PX1b) may store electrons generated by a corresponding photoelectric conversion region (e.g., PD1b), and may thus perform a global shutter operation. More explanations on the global shutter operation are provided later in this patent document.

The storage gate STG1b included in each unit pixel (e.g., PX1b) may be disposed between the photoelectric conversion region PD1b and the storage diode region SD1b. Accordingly, electrons generated by the photoelectric conversion region PD1b may be transmitted to the corresponding storage diode region SD1b based on a storage control signal applied to the storage gate STG1b.

The photoelectric conversion region (e.g., PD1b) corresponding to each storage diode region (e.g., SD1b) may be included in the same unit pixel (e.g., PX1b), and may refer to the photoelectric conversion region PD1b formed to overlap with the storage gate STG1b.

The global shutter operation may refer to an operation in which all the unit pixels PX1b˜PX8b included in the pixel array (e.g., 110 of FIG. 1) start and stop exposure to incident light at the same time so that a pixel signal corresponding to the incident light can be output for each row of the pixel array 110.

Thus, when the global shutter operation is activated, the photoelectric conversion regions PD1b˜PD8b included in the pixel array 110 can be simultaneously reset, and each of the photoelectric conversion regions PD1b˜PD8b can generate electrons corresponding to incident light simultaneously received in the photoelectric conversion regions PD1b˜PD8b.

Since the storage diode region (e.g., SD1b) included in each unit pixel (e.g., PX1b) stores electrons generated by the corresponding photoelectric conversion region (e.g., PD1b), pixel signals corresponding to electrons generated by the photoelectric conversion regions PD1b˜PD8b can be sequentially output.

The transfer gates TG1b˜TG8b may be disposed between the floating diffusion regions FD1b and FD2b and the storage diode regions SD1b˜SD8b. In more detail, the transfer gates TG1b˜TG4b may be disposed between the floating diffusion region FD1b and the storage diode regions SD1b˜SD4b, and the transfer gates TG5b˜TG8b may be disposed between the floating diffusion region FD2b and the storage diode regions SD5b˜SD8b. In addition, each transfer gate (e.g., TG1b) may be disposed to overlap with the storage diode region (e.g., SD1b) and the floating diffusion region FD1b. As the transfer control signal is applied to the transfer gate (e.g., TG1b), electrons stored in the storage diode region (e.g., SD1b) can be transmitted to the floating diffusion region (e.g., FD1b).

The pixel transistors DXb, SXb, RXb, and AXb may be formed to overlap with the unit pixels PX1b˜PX8b. In some implementations, the drive transistor DXb and the additional transistor AXb among the pixel transistors DXb, SXb, RXb, and AXb may be formed to overlap with the storage gates (e.g., STG1b, STG3b, and STG5b).

As the pixel transistors DXb, SXb, RXb, and AXb are formed in a different layer from a layer in which the transfer gates TG1b˜TG8b and the storage gates STG1b˜STG8b are disposed, the region in which the photoelectric conversion regions PD1b˜PD8b are formed can be guaranteed. In addition, the region in which the transfer gates TG1b˜TG8b and the storage gates STG1b˜STG8b are formed can also be guaranteed.

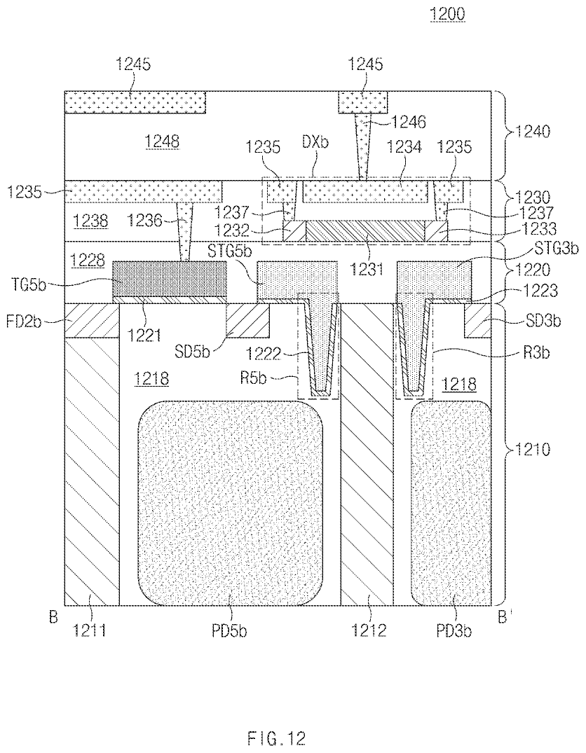

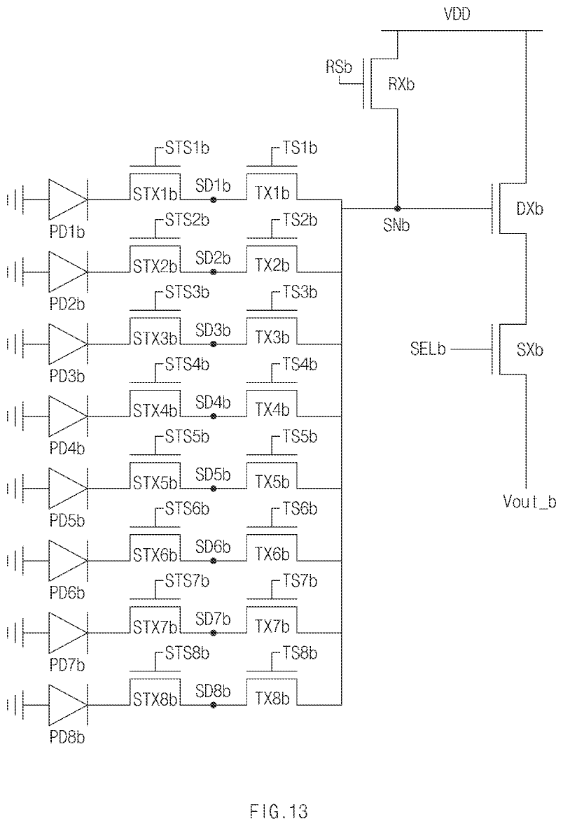

FIG. 12 is a cross-sectional view 1200 illustrating an example of the unit pixel group 1100 taken along a second cutting line B-B′ shown in FIG. 11.

Referring to FIG. 12, a substrate layer 1210, a first dielectric layer 1220, a second dielectric layer 1230, and a third dielectric layer 1240 are shown. The second dielectric layer 1230 and the third dielectric layer 1240 shown in FIG. 12 are substantially identical in structure to those of FIG. 3, and as such redundant description thereof will herein be omitted for brevity. For convenience of description, the example of FIG. 12 will hereinafter be described centering upon the substrate layer 1210 and the first dielectric layer 1220. Although the example of FIG. 12 has disclosed a portion of the unit pixel group 1200, the same concept as described above can also be applied to other regions included in the unit pixel group 1200.

The substrate layer 1210 may include isolation regions 1211 and 1212, photoelectric conversion regions PD5b and PD3b, a semiconductor region 1218, and storage diode regions SD5b and SD3b.

In some implementations, each of the storage diode regions SD5b and SD3b may include an N-type impurity doped region. Each storage diode region (e.g., SD5b) may store electrons generated by the photoelectric conversion region (e.g., PD5b) corresponding to the storage diode region SD5b. Each storage diode region (e.g., SD5b) may be formed simultaneously with formation of the floating diffusion region FD2b.

Since the storage diode region SD5b stores electrons generated by the photoelectric conversion region PD5b and the storage diode region SD3b stores electrons generated by the photoelectric conversion region PD3b, signals corresponding to incident lights respectively received in the photoelectric conversion regions PD5b and PD3b can be output through the global shutter operation during the same exposure time.

The first dielectric layer 1220 may include a transfer gate TG5b and a gate insulation layer 1221. In addition, the first dielectric layer 1220 may include storage gates STG5b and STG3b, and storage gate insulation layers 1222 and 1223.

Each of the storage gates STG5b and STG3b may include polysilicon. In addition, the storage gate STG5b may include a recessed portion R5b that extends to a predetermined length in the direction from one surface of the first dielectric layer 1220 to the substrate layer 1210, and the storage gate STG3b may include a recessed portion R3b that extends to a predetermined length in the direction from one surface of the first dielectric layer 1220 to the substrate layer 1210.

By the recessed portions R5b and R3b, an electron transfer channel can be easily formed between the photoelectric conversion region (e.g., PD5b) and the storage diode region SD5b corresponding to the photoelectric conversion region PD5b, such that electrons can easily move from the photoelectric conversion region PD5b to the storage diode region SD5b. As the recessed portions R5b and R3b are formed, electrons stored in the photoelectric conversion region can be easily transferred to the storage diode region.

The recessed portions R5b and R3b may be formed by further performing an etching process on the substrate layer 1210 in the process of forming the storage gates STG5b and STG3b and the transfer gates TG5b and TG3b at an upper portion of the substrate layer 1210.

The storage gate insulation layers 1222 and 1223 may be disposed between the substrate layer 1210 and the storage gates STG5b and STG3b. In more detail, the storage gate insulation layer 1222 may be disposed between the substrate layer 1210 and the storage gate STG5b, and the storage gate insulation layer 1223 may be disposed between the substrate layer 1210 and the storage gates STG3b. The storage gate insulation layers 1222 and 1223 may electrically and physically isolate the substrate layer 1210 and the storage gates STG5b and STG3b from each other. In more detail, the storage gate insulation layer 1222 may electrically and physically isolate the substrate layer 1210 and the storage gate STG5b from each other, and the storage gate insulation layer 1223 may electrically and physically isolate the substrate layer 1210 and the storage gate STG3b from each other.

In some implementations, the storage gates STG5b and STG3b may be formed to overlap with the pixel transistor (for example, DXb). As the pixel transistor DXb overlaps with the storage gates STG5b and STG3b, the region in which the photoelectric conversion regions PD5b and PD3b are formed and the other region in which the storage gates STG5b and STG3b are formed can be guaranteed.

FIG. 13 is a circuit diagram illustrating an example of an equivalent circuit of a unit pixel group (e.g., 1100 of FIG. 11) based on another embodiment of the disclosed technology.

Referring to FIG. 13, eight photoelectric conversion regions PD1b˜PD8b, storage transistors STX1b˜STX8b respectively connected to the photoelectric conversion regions PD1b˜PD8b, and storage diodes SD1b˜SD8b respectively connected to the storage transistors STX1b˜STX8b are shown. The remaining circuits other than the storage transistors STX1b˜STX8b and the storage diodes SD1b˜SD8b shown in FIG. 13 are substantially the same as those of FIG. 4, and thus such redundant description will herein be omitted for brevity.

Each storage transistor (e.g., STX1b) may include a storage gate (e.g., STG1b of FIG. 11) corresponding thereto. Storage control signals STS1b˜STS8b may be applied to storage transistors STX1b˜STX8b, respectively. Electrons generated by the photoelectric conversion regions PD1b˜PD8b may be transferred to the storage diodes SD1b˜SD8b through the corresponding storage transistors STX1b˜STX8b based on voltage levels of the storage control signals STS1b˜STS8b, respectively.

The storage diodes SD1b˜SD8b may store electrons received through the storage transistors STX1b˜STX8b. The transfer signals TS1b˜TS8b may sequentially have an activation voltage according to the operation time points of the transfer transistors TX1b˜TX8b. The transfer transistors TX1b˜TX8b to which the transfer signals TS1b˜TS8b each having an activation voltage are respectively applied may transmit electrons stored in the storage diodes SD1b˜SD8b to the sensing node SNb.

Signals corresponding to electrons by the respective photoelectric conversion regions PD1b˜PD8b can be sequentially sensed based on a voltage change caused by electrons transferred to the sensing node SNb. The voltage change corresponding to electrons generated by the photoelectric conversion regions PD1b˜PD8b can be amplified by the drive transistor DXb. A pixel signal Vout_b amplified by the drive transistor DXb can be selectively output through the selection transistor SXb.

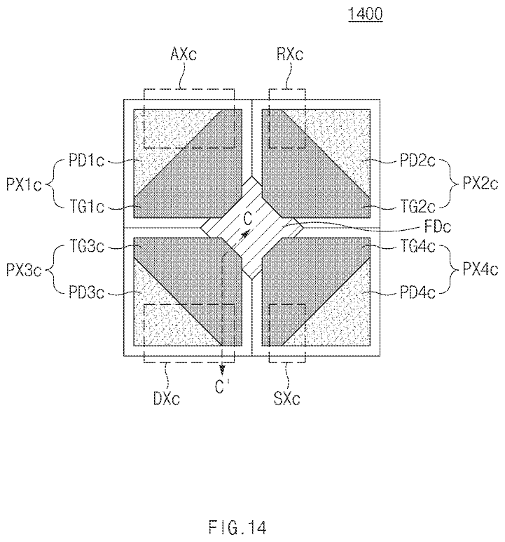

FIG. 14 is a schematic diagram illustrating an example of a unit pixel group 1400 included in an image sensing device (e.g., 100 of FIG. 1) based on still another embodiment of the disclosed technology. As depicted in FIG. 14, the plurality of unit pixel groups 1400 may be repeatedly arranged in a pixel array (e.g., 110 of FIG. 1).

In still another embodiment, the unit pixel group 1400 may include four unit pixels PX1c˜PX4c. The four adjacent unit pixels PX1c˜PX4c may share only one floating diffusion region FDc.

Each unit pixel (e.g., PX1) may include a photoelectric conversion region (e.g., PD1c) and a transfer gate (e.g., TG1c).

The unit pixels PX1c˜PX4c may overlap with pixel transistors DXc, SXc, RXc, and AXc. As the pixel transistors DXc, SXc, RXc, and AXc are formed in a different layer from the transfer gates TG1c˜TG4c, the region in which photoelectric conversion regions PD1c˜PD4c are formed can be guaranteed even in the layout structure in which four unit pixels PX1c˜PX4c share the pixel transistors DXc, SXc, RXc, and AXc.

Thus, when the transfer gates TG1c˜TG4c and the pixel transistors DXc, SXc, RXc, and AXc are formed in the same layer, the region in which the photoelectric conversion regions PD1c˜PD4c are formed can be restricted to guarantee the formation region of the pixel transistors DXc, SXc, RXc, and AXc, and the pixel transistors DXc, SXc, RXc, and AXc can be formed to share the eight unit pixels, such that the formation region of the photoelectric conversion regions PD1c˜PD4c can be guaranteed.

When the transfer gates TG1c˜TG4c are formed in a different layer from the pixel transistors DXc, SXc, RXc, and AXc, the formation region of the pixel transistors DXc, SXc, RXc, and AXc can be guaranteed regardless of the shapes of the transfer gates TG1c˜TG4c.

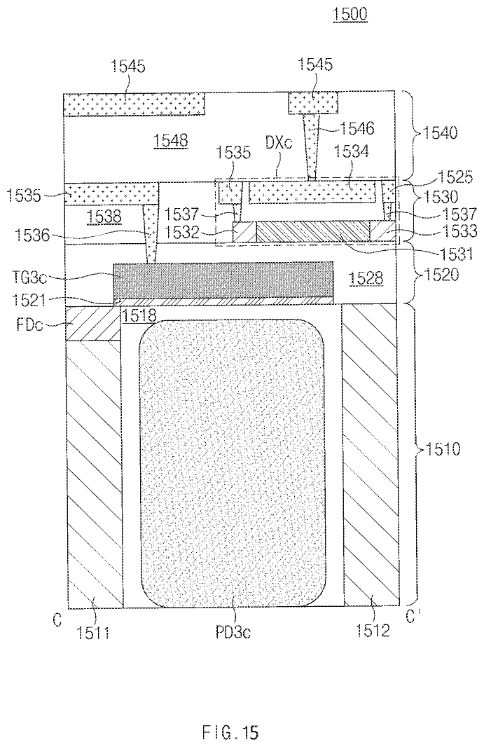

FIG. 15 is a cross-sectional view 1500 illustrating an example of a unit pixel group 1400 taken along a third cutting line C-C′ shown in FIG. 14.

Referring to FIG. 15, a substrate layer 1510, a first dielectric layer 1520, a second dielectric layer 1530, and a third dielectric layer 1540 are shown. As can be seen from the cross-sectional view of FIG. 15, the remaining elements other than the position of the pixel transistor DXc included in the second dielectric layer 1530 are substantially identical to those of FIG. 3, and as such redundant description thereof will herein be omitted. Thus, the example of FIG. 15 will hereinafter be described centering upon the pixel transistor DXc for convenience of description.

The pixel transistor DXc may be formed to overlap with a transfer gate TG3c formed in the first dielectric layer 1520. Here, the pixel transistor DXc may be formed to overlap with only one transfer gate TG3c, and one type of pixel transistors may be allocated to the unit pixel groups 1400 on a one-to-one basis. That is, the same type of pixel transistors can be included in the unit pixel groups 1400 on a one-to-one basis. As the unit pixel group 1400 includes four unit pixels (e.g., PX1c˜PX4c of FIG. 14), the overlap position of the pixel transistor DXc can be changed.

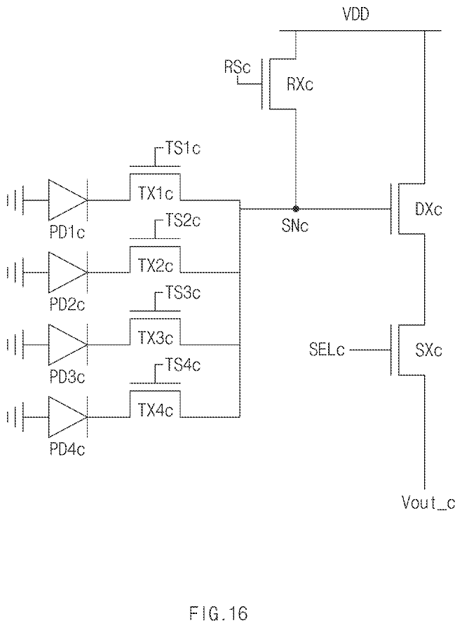

FIG. 16 is a circuit diagram illustrating an example of an equivalent circuit of a unit pixel group (e.g., 1400 of FIG. 14) based on still another embodiment of the disclosed technology.

Referring to FIG. 16, four photoelectric conversion regions PD1c˜PD4c, transfer transistors TX1c˜TX4c connected to the photoelectric conversion regions PD1c˜PD4c, and a sensing node SNc connected to the transfer transistors TX1c˜TX4c are shown.

The unit pixel group (e.g., 1400 of FIG. 14) based on still another embodiment may allow four unit pixels (e.g., PD1c˜PD4c of FIG. 14) to share only one floating diffusion region FDc, such that capacitance of the sensing node SNc may be identical to capacitance of the floating diffusion region FDc shown in FIG. 14. The remaining circuits other than the number of unit pixels connected to the sensing node SNc are substantially identical to those of FIG. 4, and as such redundant description thereof will herein be omitted for brevity.

Electrons generated by the photoelectric conversion regions PD1c˜PD4c may be transmitted to the sensing node SNc through the transfer transistors TX1c˜TX4c, respectively. In more detail, electrons generated by the photoelectric conversion regions PD1c˜PD4c may be transmitted to the sensing node SNc based on transfer control signals TS1c˜TS4c applied to the transfer transistors TX1c˜TX4c.

The drive transistor DXc, the reset transistor RXc, and the selection transistor SXc may be substantially identical in function and connection relationship to those of FIGS. 4 and 13.

Electrons generated by the photoelectric conversion regions PD1c˜PD4c can be output as a corresponding pixel signal Vout_c.

As is apparent from the above description, the image sensing device based on some implementations of the disclosed technology is configured in a manner that pixel transistors to be included in the image sensing device are formed in a different layer from transfer gates so that a region in which the pixel transistors are disposed can be guaranteed, resulting in an increased degree of freedom in forming such pixel transistors.

The image sensing device based on some implementations of the disclosed technology can form gate electrodes of the pixel transistors together with metal lines, resulting in a simplified process of forming such pixel transistors.

The image sensing device based on some implementations of the disclosed technology can allow the metal lines adjacent to each other to be isolated from each other by an insulation layer formed to isolate gate electrodes of the pixel transistors from channel regions of the pixel transistors.

In addition, the image sensing device based on some implementations of the disclosed technology can form a storage transistor and a storage diode region in the region that has been guaranteed by forming the pixel transistors in a different layer from the transfer gates, thereby performing a global shutter operation.

The embodiments of the disclosed technology may provide a variety of effects capable of being directly or indirectly recognized through the above-mentioned patent document.

Those skilled in the art will appreciate that the disclosed technology may be carried out in other ways than those set forth herein. Certain features that are described in this patent document in the context of separate embodiments can also be implemented in combination in a single embodiment. Conversely, various features that are described in the context of a single embodiment can also be implemented in multiple embodiments separately or in any suitable subcombination.

Although a number of illustrative embodiments of the disclosed technology have been described, various modifications or enhancements to the disclosed embodiments and other embodiments can be devised based on what is described and/or illustrated in this patent document.

What is claimed is:

1. An image sensing device comprising:
a substrate layer structured to include a plurality of photoelectric conversion regions that respond to incident light to generate electrons, and a plurality of floating diffusion regions coupled to the plurality of photoelectric conversion regions, respectively, and structured to store the electrons generated by the plurality of photoelectric conversion regions, respectively;
a first dielectric layer disposed over the substrate layer; and
a second dielectric layer disposed over the first dielectric layer, and including a plurality of metal lines and a pixel transistor,
wherein the pixel transistor includes:
a gate electrode receiving a control signal for the pixel transistor;
a channel region formed under the gate electrode; and
an insulation layer between the gate electrode and the channel region to isolate the gate electrode and the channel region from each other, and isolate adjacent metal lines from each other.

2. The image sensing device according to claim 1, wherein the second dielectric layer includes an additional pixel transistor that is adjacent to the pixel transistor, and the insulation layer isolates the pixel transistor and the additional pixel transistors from each other.

3. The image sensing device according to claim 1, wherein the first dielectric layer includes:
a plurality of transfer gates transmitting the electrons generated by the plurality of photoelectric conversion regions to the plurality of floating diffusion region.

4. The image sensing device according to claim 3, wherein:
each of the plurality of transfer gates overlaps with a corresponding photoelectric conversion regions and a corresponding floating diffusion regions.

5. The image sensing device according to claim 3, wherein:
the pixel transistor overlaps with at least one of the plurality of transfer gates.

6. The image sensing device according to claim 1, wherein:
the pixel transistor is implemented as a drive transistor amplifying a signal corresponding to the electrons received from the plurality of floating diffusion regions, a selection transistor selectively outputting the signal, a reset transistor resetting a voltage of the floating diffusion region, or any other transistor.

7. The image sensing device according to claim 3, wherein:
the plurality of photoelectric conversion regions includes four photoelectric conversion regions that are arranged in a matrix array to be adjacent to each other; and
one floating diffusion region is disposed at a center of the matrix array to have portions overlapping with the four photoelectric conversion regions.

8. The image sensing device according to claim 7, wherein:
the pixel transistor is coupled to at least two floating diffusion regions adjacent to each other.

9. The image sensing device according to claim 7, wherein:
the pixel transistor is coupled to the one floating diffusion region.

10. The image sensing device according to claim 1, wherein:
the substrate layer further includes a plurality of storage diode regions storing the electrons, and
the first dielectric layer includes:
a plurality of storage gates transmitting the electrons generated by the plurality of photoelectric conversion regions to the plurality of storage diode regions; and
a plurality of transfer gates transmitting the electrons stored in the plurality of storage diode regions to the plurality of floating diffusion regions.

11. The image sensing device according to claim 10, wherein each of the plurality of storage gates includes:
a recessed portion extending in a direction from one surface of the first dielectric layer to the substrate layer and having a predetermined length.

12. The image sensing device according to claim 10, wherein:
each of the plurality of storage gates is disposed to overlap with a corresponding photoelectric conversion region and a corresponding storage diode region.

13. The image sensing device according to claim 10, wherein:
each of the plurality of transfer gates is disposed to overlap with a corresponding storage diode region and a corresponding floating diffusion region.

14. The image sensing device according to claim 10, wherein:
the pixel transistor is disposed to overlap with at least one of the plurality of storage gates.

15. The image sensing device according to claim 14, wherein:
the gate electrode includes same material as the metal lines.

16. A method for manufacturing an image sensing device, comprising:
forming a photoelectric conversion region in a substrate layer, the photoelectric conversion region producing electrons in response to a reception of incident light;
forming a floating diffusion region in the substrate layer, the floating diffusion region coupled to the photoelectric conversion region and storing the electrons produced in the photoelectric conversion region;
forming a transfer gate at an upper portion of the substrate layer;
forming a first dielectric layer by depositing a first dielectric material over the transfer gate;
forming a semiconductor region over the first dielectric layer;
forming a pixel transistor including a source region, a channel region, and a drain region in the semiconductor region;
depositing a second dielectric material over the semiconductor region to provide a second dielectric layer; and
forming a metal line and a gate electrode in the second dielectric layer.

17. The method according to claim 16, further comprising:
forming a storage diode region in the substrate layer; and
forming a storage gate including a recessed portion that extends to a predetermined length in a direction from an upper portion of the substrate layer to a lower portion of the substrate layer.

18. The method according to claim 16, wherein the gate electrode is formed through a same process for forming the metal line.

19. The method according to claim 16, wherein the pixel transistor is formed to overlap with the transfer gate.

20. The method according to claim 16, wherein the gate electrode is formed to overlap with the source region of the pixel transistor.
